(19) United States
(12) Patent Application Publication
(10) Pub. No.: US 2008/0316691 A1
(43) Pub. Date: Dec. 25, 2008

(54) Configurable Computer System and Methods of Use

(75) Inventor: Gregory E. Arends, Cedar Park, TX (US)

Correspondence Address: Houston IP Department;JACKSON WALKER L.L.P., 1401 McKinney St., Suite 1900, Houston, TX, 77010, US

(73) Assignee: XPLORE TECHNOLOGIES CORPORATION OF AMERICA

(21) Appl. No.: 12/134,603

(22) Filed: Jun. 6, 2008

Related U.S. Application Data
(60) Provisional application No. 60/933,549, filed on Jun. 7, 2007.
(60) Provisional application No. 60/933,629, filed on Jun. 7, 2007.
(60) Provisional application No. 60/933,935, filed on Jun. 8, 2007.

(51) Int. Cl. H05K 7/00; H05K 13/04

(52) U.S. Cl. 361/681; 361/683; 29/729

(57) ABSTRACT

Methods and devices are provided that allow for a configurable computer system comprised of a common electronic base used in conjunction with interchangeable user interface system housings having a tablet display, a notebook display, or convertible display. The user interface systems comprise an upper housing that interfaces with the common electronic base through a personality module comprised of a configuration module connector and a configuration module. The physical structure and arrangement of the common electronic base and the personality module is designed to allow for interchangeability of two or more of the following: a tablet display, a notebook computer keyboard and notebook display, and a convertible display having a keyboard and a convertible display.

### CROSS-REFERENCE TO RELATED APPLICATION

The present application claims priority to and the benefit of U.S. provisional patent application Ser. No. 60/933,549, filed on Jun. 7, 2007, U.S. provisional patent application Ser. No. 60/933,629, filed on Jun. 7, 2007, U.S. provisional patent application Ser. No. 60/933,935, filed on Jun. 8, 2007, which are hereby incorporated by reference.

### BACKGROUND

The present application relates to configurable computer systems having a common electronic base.

Computer manufacturers typically produce a number of different types of computer systems. For example, a portable computer manufacturer may manufacture notebook computers, tablet computers, and convertible computers. Generally, each of these computer types are designed to allow a high level of manufacturing efficiency. While some degree of common subassemblies may be found in similar models from a given manufacturer, it is more typical to find commonality only at a component level, such as, for example, a hard drive, a DVD drive or a power unit.

Accordingly, different unique designs are conceived for each notebook computers, tablet computer, or convertible computer. Each unique portable computer design requires a certain duration of time to fabricate the particular configuration, often referred to as a “build time.” The uniqueness of each configuration's design may allow manufacturing optimization and efficiency with respect to the production of each design, but at the same time, such uniqueness in the designs adversely impacts the manufacturer's flexibility in reallocating computer components to other designs. Additionally, in low-production applications, such as the rugged notebook/tablet manufacturing environments, unique non-interchangeable components adversely affect a manufacturer's ability to repair and reconfigure computer systems to fulfill customer demands. Moreover, lack of interchangeability results in a delay of some of the important decisions regarding a manufacturer's product mix until near the end of the individual unit's flow through manufacturing, thus delaying fulfillment of customer orders.

The build time associated with portable computer configuration delays fulfillment of customer orders when manufacturers delay production of each portable computer until receipt of a customer order. Alternatively, a computer manufacturer may build up an inventory of different portable computer configurations in anticipation of future customer orders. Because of the difficulty in estimating future orders, one disadvantage of fabricating portable computers before the receipt of corresponding orders is an unnecessary build-up in inventory of computer models due to overestimated customer orders. Conversely, fulfillment of customer orders are delayed due to underestimated of customer orders.

Thus, it is desirable to minimize inventory costs (e.g. resulting from an over-estimation of customer orders), while at the same time minimizing customer order fulfillment times. On the one hand, over-estimating customer orders results in higher inventory costs. Conversely, under-estimating customer orders results in delayed customer fulfillment due to the build time associated with each particular portable computer configuration.

Consequently, computer manufacturers are faced with the difficult choice of incurring higher inventory costs or delaying fulfillment of customer orders. Thus, it is desirable to minimize product design configuration build times so as to minimize inventory costs, decrease customer order fulfillment time, decrease costs, and increase efficiencies.

### SUMMARY

The present application relates to configurable computer systems having a common electronic base.

Methods and devices of the present invention allow for a configurable computer system comprised of a common electronic base used in conjunction with interchangeable user interface system housings having a tablet display, a notebook display, or convertible display. In particular, a tablet computer, a notebook computer, or a convertible computer may be produced from a common electronic base that interfaces with a tablet housing, a notebook housing, or a convertible housing, provided that each user interface housing presents a common interface to the common electronic base via a configuration or personality module on the bottom of the user interface housing. The common electronic base is identical for all three computer configurations.

The interchangeability of the system components also allows existing inventory to be reconfigured and allows a manufacturer to update their product mix at any time. In this way, certain embodiments of the present invention improve materials management and enhance manufacturing flow and forecasting as exemplified in the computer industry.

One example of a method for configuring a portable computer system comprises the steps of: providing a common electronic base, the common electronic base comprising a lower housing, a main logic board attached to the lower housing, and a configuration module connector in electrical communication with the main logic board and structurally attached to one of the main logic board and the lower housing; wherein the configuration module connector interfaces and communicates with a configuration module; providing an upper housing that interfaces with the lower housing wherein the upper housing is one of the following: (a) a tablet display; (b) a notebook computer keyboard and notebook display; and (c) a convertible display having a keyboard and a convertible display; wherein the configuration module is adapted to communicatively couple individually to (a), (b), and (c); and wherein the physical structure and arrangement of the common electronic base and the configuration module connector allow for interchangeability of (a), (b), or (c).

An example of a configurable computer system comprises a lower housing; a main logic board attached to the lower housing; a configuration module connector in electrical communication with the main logic board and structurally attached to one of the main logic board and the lower housing; wherein the configuration module connector interfaces and communicates with a configuration module; and an upper housing that interfaces with the lower housing; wherein the upper housing is one of the following: (a) a tablet display; (b) a notebook computer keyboard and notebook display; and (c) a convertible display having a keyboard and a convertible display; wherein the configuration module is adapted to communicatively couple individually to (a), (b), and (c).

One example of a configurable computer system comprises a common electronic base, the common electronic base comprising a lower housing, a main logic board attached to the lower housing, and a configuration module connector in electrical communication with the main logic board and structurally attached to one of the main logic board and the lower housing; wherein the configuration module connector interfaces and communicates with a configuration module; an upper housing that interfaces with the lower housing; wherein the upper housing is one of the following: (a) a tablet display; (b) a notebook computer keyboard and notebook display; and (c) a convertible display having a keyboard and a convertible display; wherein the configuration module is adapted to communicatively couple to (a), (b), or (c); and wherein the physical structure and arrangement of the common electronic base and the configuration module connector allow for interchangeability of (a), (b), or (c).

The features and advantages of the present invention will be apparent to those skilled in the art. While numerous changes may be made by those skilled in the art, such changes are within the spirit of the invention.

### BRIEF DESCRIPTION OF THE DRAWINGS

A more complete understanding of the present disclosure and advantages thereof may be acquired by referring to the following description taken in conjunction with the accompanying figures, wherein:

FIG. 1A illustrates a perspective exploded view of a configurable computer system configuration in accordance with one embodiment of the present invention.

FIG. 1B illustrates a cross-sectional close-up view of a configurable computer system configuration in accordance with one embodiment of the present invention.

FIG. 2 illustrates the interchangeability of a common electronic base to a variety of portable computer system configurations.

While the present invention is susceptible to various modifications and alternative forms, specific exemplary embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DESCRIPTION OF PREFERRED EMBODIMENTS

The present application relates to configurable computer systems having a common electronic base.

Methods and devices of the present invention allow for a configurable computer system comprised of a common electronic base used in conjunction with interchangeable user interface system housings. While such user interface system housings may take many forms, for purposes of describing the invention, the description herein will refer to three such possible housings in order to illustrate the invention, namely a tablet display, a notebook display, or convertible display. However, use of such illustrative example throughout the specification should not be construed as limiting the invention to this particular quantity or type of housings. In this regard, interchangeability of at least two housings would satisfy one embodiment of the invention, while interchangeability of all three of the illustrative housings would satisfy another embodiment of the invention.

In particular, a tablet computer, a notebook computer, or a convertible computer may be produced from a common electronic base that interfaces with multiple housings, namely a tablet housing, a notebook housing, or a convertible housing, provided that each user interface housing presents a common interface to the common electronic base via a configuration or personality module on the bottom of the user interface housing. The common electronic base is identical for all three computer configurations.

The interchangeability of the system components also allows existing inventory to be rapidly reconfigured and allows a manufacturer to update their product mix at any time. In this way, certain embodiments of the present invention improve materials management and enhance manufacturing flow and forecasting as exemplified in the computer industry.

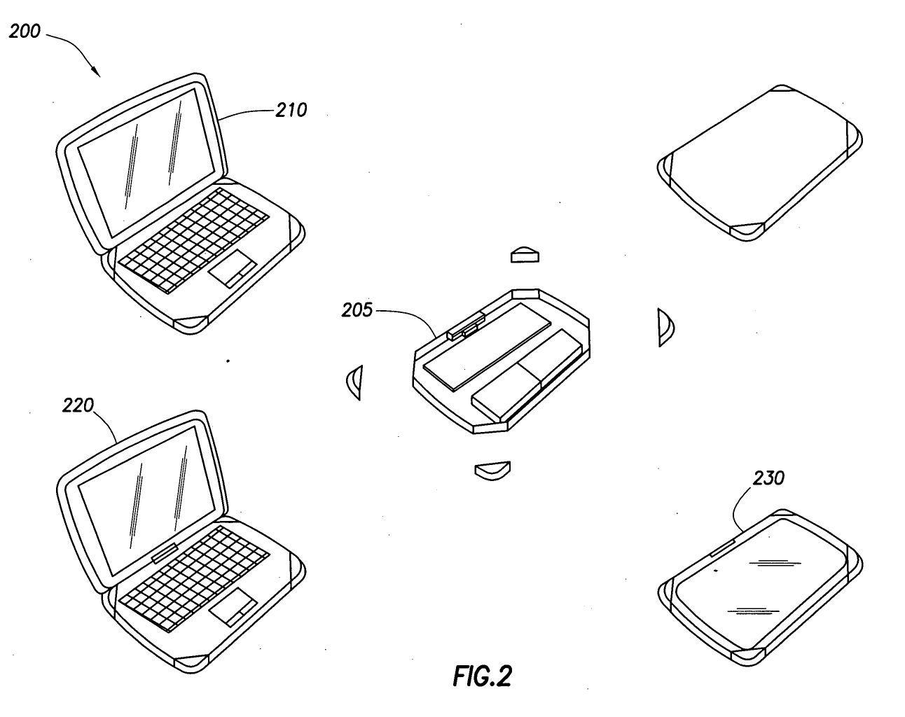

Examples of suitable portable computer systems of the present invention that may be produced via the interchangeable components discussed herein include notebook computers, tablet computers, and convertible computers. The term, “notebook computer,” as used herein, refers to a portable computer having a notebook display. The term, “notebook display,” as used herein, refers to a computer display attached to a notebook base with a hinge that opens from a closed position to an open position about one axis of rotation (e.g. notebook display 210 as shown in FIG. 2). The term, “tablet computer,” as used herein, refers to a tablet-style or slate computer having a tablet display. The term, “tablet display,” as used herein, refers to a computer display that allows the user to operate the computer with a stylus or digital pen, or a fingertip (e.g. tablet display 220 as shown in FIG. 2). The term, “convertible computer,” as used herein, refers to a notebook computer having a convertible display. The term, “convertible display,” as used herein, refers to a computer display attached to a notebook base with a hinge that opens from a closed position to an open position about a first axis of rotation and rotates about a second axis perpendicular to the first axis wherein the computer display is capable of converting to a tablet-style display by opening 90° from a closed position, rotating 180° about the second axis, and then closing with the convertible display in an exposed position accessible for user input (e.g. notebook display 230 as shown in FIG. 2).

Each of these portable computer systems (e.g. notebook, tablet, and convertible computers) share common circuitry with the exception of their human interfaces (e.g., enclosures, displays, and keyboards).

Without the present invention, it is necessary to select the enclosure, display and interface type for an individual serial number unit at the start of the manufacturing process. In this case the planning, forecasting and materials purchase must be established well before the start of manufacture. With the current invention, some of the important decisions regarding the product mix may be delayed until near the end of the individual unit's flow through manufacturing. With the current invention, existing inventory can also be reconfigured, allowing the product mix to be updated at any time.

In certain embodiments, a configurable computer system comprises a lower housing having a main logic board therein. The main logic board communicates with the user interface systems through a configuration module. The physical structure and arrangement of the lower housing and the configuration modules allow for the interchangeability of different user interface systems, such as for example, a tablet display, a notebook display or a convertible display. Each user interface system comprises a configuration module that communicates with the main logic board through the configuration module connector.

The user interface systems comprise an upper housing that interfaces with the lower housing. Suitable upper housings of the present invention may be any one of the following: (a) a tablet display, (b) a notebook computer keyboard and notebook display, and (c) a convertible display having a keyboard and a convertible display wherein the configuration module is adapted to communicatively couple individually to (a), (b), and (c). The physical structure and arrangement of the lower housing and the configuration module connector is designed to allow for interchangeability of three or more of the following: a tablet display, a notebook computer keyboard and notebook display, and a convertible display having a keyboard and a convertible display.

To facilitate a better understanding of the present invention, the following examples of certain embodiments are given. In no way should the following examples be read to limit, or define, the scope of the invention.

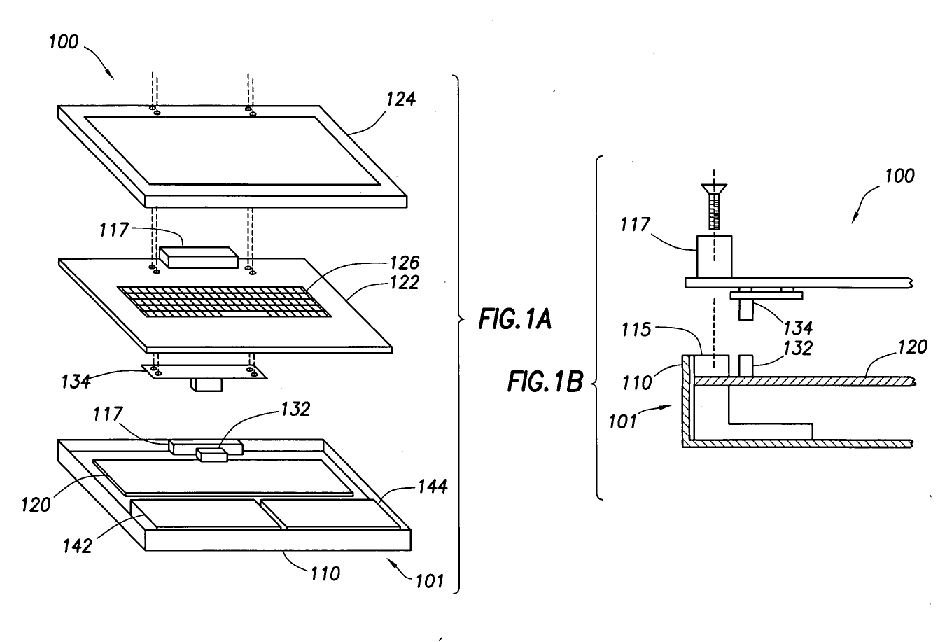

FIGS. 1A and 1B illustrate a perspective exploded view and cross-sectional view, respectively, of a multiple-configurable portable computer configuration in accordance with one embodiment of the present invention.

Portable computer system 100 may be configured as a tablet computer, a notebook computer, or a convertible computer. Upper tablet housing 124 may be selected to configure a tablet computer, whereas upper notebook or convertible housing 122 may be selected to configure a notebook or convertible computer. In each case, common electronic base 101 forms part of portable computer system 100.

More specifically, portable computer system 100 comprises common electronic base 101, configuration module 134, and upper housing 122 or 124. Common electronic base 101 comprises lower housing 110, hinge mounting block 115, main logic board 120, configuration module connector 132, power module 142 such as a battery, and a data storage or memory device 144, such as a hard drive.

Configuration module connector is communicatively coupled to configuration module 134 to communicate user interface data between main logic board 120 and the user interface devices associated with upper housing 122 or 124. In this way, configuration module connector is adapted to communicate the type of interface used in conjunction with common electronic base 101 via communications through configuration module 134. That is, configuration module 134 identifies the type of interface (e.g. table, notebook, or convertible computer) that is used in conjunction with common electronic base 101. Although configuration module connector 132 is shown here as structurally attached to main logic board 120, it is recognized that configuration module connector 132 may be structurally attached directly to hinge mounting block 120 or to lower housing 110.

Where portable computer system 100 is configured as a tablet computer, common electronic base 101 is joined with upper housing 124. Where portable computer is configured as a notebook or convertible computer, common electronic base 101 is joined with upper housing 122. Hinge turret 117 is available on upper housing 122 but not with upper housing 124. Hinge turret 117 provides an attachment and rotation point for a notebook or convertible display (not shown). Where the display is a notebook display, hinge turret 117 allows the display to open and close about one axis of rotation. Although not intended as a limitation herein, typically, hinge turrets for notebook displays allow rotation of a screen from the closed position (about 0°) to about 145° open. In certain embodiments, notebook displays are capable of opening to about 180° or more). Where the display is a convertible notebook, hinge turret 117 allows rotation of the display about two axis of rotation. Keyboard 126 is available in upper housing 122 as one method for providing user input.

In certain embodiments, configuration module connector 132 and configuration module 134 are together referred to as a personality module. The personality module communicates to main logic board 120 the type of interface being used. Configuring a common electronic base to accept multiple interfaces and input/output systems allows portable computer systems to be reconfigured from one type of system to another (e.g. a notebook computer to a convertible computer). Additionally, repair of such systems is simplified due to the interchangeability of the parts.

Furthermore, multiple-configurable computer systems of the present invention allow most of a computer system to be constructed before knowing the specific customer order details related to the number and types of computer systems desired. In this way, customer fulfillment times are reduced through a reduction in build-time, and inventory costs are reduced.

Any of the features and components disclosed in Applicant's concurrently filed non-provisional patent applications may be used in conjunction with embodiments of the present invention, namely U.S. patent application Ser. No. ______, entitled “Electronic Enclosure Fastening Belt” (which claims priority to U.S. Provisional Application Ser. No. 60/933,549) and U.S. patent application Ser. No. ______, entitled “Electronic Enclosure Having Elastomeric Circuit Board Standoffs” (which claims priority to U.S. Provisional Application Ser. No. 60/933,935), the specifications of which are hereby incorporated by reference. In particular, it is explicitly recognized that embodiments described in these concurrently-filed specifications may be used in conjunction with the embodiments herein to eliminate traditional fasteners.

FIG. 2 illustrates the interchangeability of a common electronic base to a variety of portable computer system configurations. As a further illustration of the interchangeability of a common electronic base with various user interface systems affixed thereto, FIG. 2 shows common electronic base 205, which may be configured as a notebook computer 210, a convertible computer 220, or a tablet computer 230.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee.

What is claimed is:

1. A method for configuring a portable computer system comprising the steps of:
providing a common electronic base, the common electronic base comprising a lower housing, a main logic board attached to the lower housing, and a configuration module connector in electrical communication with the main logic board and structurally attached to one of the main logic board and the lower housing;
wherein the configuration module connector interfaces and communicates with a configuration module;
providing an upper housing that interfaces with the lower housing wherein the upper housing is one of the following:
(a) a tablet display;
(b) a notebook computer keyboard and notebook display; and
(c) a convertible display having a keyboard and a convertible display;
wherein the configuration module is adapted to communicatively couple individually to at least two of the upper housings (a), (b), and (c); and wherein the physical structure and arrangement of the common electronic base and the configuration module connector allow for interchangeability of at least two of the upper housings (a), (b), and (c).

2. The method of claim 1 wherein the configuration module is adapted to communicatively couple individually to all three of the upper housings (a), (b), and (c); and wherein the physical structure and arrangement of the common electronic base and the configuration module connector allow for interchangeability of all three of the upper housings (a), (b), and (c).

3. The method of claim 1 wherein the lower housing comprises a hinge mounting block and wherein the main logic board is affixed to the hinge mounting block.

4. The configurable computer system of claim 3 wherein the configuration module connector is structurally mounted on the main logic board.

5. The configurable computer system of claim 1 wherein the configuration module connector is structurally mounted on the hinge mounting block or the lower housing.

6. The configurable computer system of claim 1 further comprising a hinge turret attached to the lower housing wherein the hinge turret is adapted to receive the notebook display that allows the notebook display to open at an angle from about 0° to about 145°.

7. The configurable computer system of claim 1 further comprising a hinge turret attached to the lower housing wherein the hinge turret is adapted to receive the convertible display that allows the convertible display to open along a first axis at an angle from about 0° to about 145° and that allows the convertible display to rotate at an angle from about 0° to at least about 180° along a second axis perpendicular to the first axis.

8. A configurable computer system comprising:
a lower housing;
a main logic board attached to the lower housing;
a configuration module connector in electrical communication with the main logic board and structurally attached to one of the main logic board and the lower housing;
wherein the configuration module connector interfaces and communicates with a configuration module; and
an upper housing that interfaces with the lower housing;
wherein the upper housing is one of the following:
(a) a tablet display;
(b) a notebook computer keyboard and notebook display; and
(c) a convertible display having a keyboard and a convertible display;
wherein the configuration module is adapted to communicatively couple individually to at least two of the housings (a), (b), and (c).

9. The configurable computer system of claim 8 wherein the configuration module is adapted to communicatively couple individually to all three of the housings (a), (b), and (c).

10. The configurable computer system of claim 8 wherein the physical structure and arrangement of the lower housing and the configuration module connector allow for interchangeability of all three of the housings (a), (b), or (c).

11. The configurable computer system of claim 10 wherein the physical structure and arrangement of the lower housing and the configuration module connector allow for interchangeability of all three of the housings (a), (b), or (c).

12. The configurable computer system of claim 8 wherein the lower housing comprises a hinge mounting block and wherein the main logic board is affixed to the hinge mounting block.

13. The configurable computer system of claim 9 wherein the configuration module connector is structurally mounted on the main logic board.

14. The configurable computer system of claim 9 wherein the configuration module connector is structurally mounted on the hinge mounting block or the lower housing.

15. The configurable computer system of claim 8 further comprising a hinge turret attached to the lower housing wherein the hinge turret is adapted to receive the notebook display that allows the notebook display to open at an angle from about 0° to about 145°.

16. The configurable computer system of claim 8 further comprising a hinge turret attached to the lower housing wherein the hinge turret is adapted to receive the convertible display that allows the convertible display to open along a first axis at an angle from about 0° to about 145° and that allows the convertible display to rotate at an angle from about 0° to at least about 180° along a second axis perpendicular to the first axis.

17. A configurable computer system comprising:
a common electronic base, the common electronic base comprising a lower housing, a main logic board attached to the lower housing, and a configuration module connector in electrical communication with the main logic board and structurally attached to one of the main logic board and the lower housing;
wherein the configuration module connector interfaces and communicates with a configuration module;
an upper housing that interfaces with the lower housing;
wherein the upper housing is one of the following:
(a) a tablet display;
(b) a notebook computer keyboard and notebook display; and
(c) a convertible display having a keyboard and a convertible display;
wherein the configuration module is adapted to communicatively couple to at least two of the housings (a), (b), or (c); and wherein the physical structure and arrangement of the common electronic base and the configuration module connector allow for interchangeability of at least two of the housings (a), (b), or (c).

18. The configurable computer system of claim 17 wherein the configuration module is adapted to communicatively couple individually to all three of the housings (a), (b), and (c).

19. The configurable computer system of claim 17 wherein the physical structure and arrangement of the lower housing and the configuration module connector allow for interchangeability of all three of the housings (a), (b), or (c).

20. A method for manufacturing computers, said method comprising the steps of:
assembling a base electronic section;
selecting an interface assembly;
assembling the base section and the selected interface assembly to produce a computer,
wherein the step of selecting an interface assembly occurs after the base electronic section has been assembled.

21. A method for manufacturing computers, said method comprising the steps of:
pre-assembling a base electronic section having at least a microprocessor, a memory module, and a power module, and further including electrical contacts disposed adjacent at least one outer surface of said base electronic section;
selecting an pre-assembled user interface housing from a group consisting of at least a table interface assembly and a notebook interface assembly, wherein each of the interface assemblies includes electrical contacts adjacent at least one outer surface of said interface assembly;
joining the base electronics section with the selected interface assembly so that said electrical contacts of are in electrical communication with one another,
wherein the step of selecting a pre-assembled user interface occurs after the base electronic section has been assembled.

22. The method of claim 21 wherein the base electronics section includes a first mounting structure and each interface section is provided with a second mounting structure and
wherein the first mounting structure of the base electronics section can be engaged with the second mounting structure of any of the interface sections.

23. A configurable computer system comprising:
a common electronic base, the common electronic base comprising a lower housing, a main logic board attached to the lower housing, and a configuration module connector in electrical communication with the main logic board and structurally attached to one of the main logic board and the lower housing;
wherein the configuration module connector interfaces and communicates with a configuration module;
an upper housing that interfaces with the lower housing;
wherein the upper housing is one of at least two different user interface system housings with different user interface functionality,
wherein the configuration module is adapted to communicatively couple to the least two user interface housings; and
wherein the physical structure and arrangement of the common electronic base and the configuration module connector allow for interchangeability of the at least two user interface housings.

24. A method for configuring a portable computer system comprising the steps of:
providing a common electronic base, the common electronic base comprising a lower housing, a main logic board attached to the lower housing, and a configuration module connector in electrical communication with the main logic board and structurally attached to one of the main logic board and the lower housing;
wherein the configuration module connector interfaces and communicates with a configuration module;
providing an upper housing that interfaces with the lower housing wherein the upper housing is one of at least two different user interface system housings with different user interface functionality,
wherein the configuration module is adapted to communicatively couple to the least two user interface housings; and
wherein the physical structure and arrangement of the common electronic base and the configuration module connector allow for interchangeability of the at least two user interface housings.
